(19) United States
(12) Patent Application Publication
(10) Pub. No.: US 2010/0038776 A1
(43) Pub. Date: Feb. 18, 2010

(54) MINIATURE MICROWAVE PACKAGE AND PROCESS FOR FABRICATING THE PACKAGE

(75) Inventor: Alexandre Bessemoulin, Chatillon (FR)

Correspondence Address: LOWE HAUPTMAN HAM & BERNER, LLP, 1700 DIAGONAL ROAD, SUITE 300, ALEXANDRIA, VA, 22314, US

(73) Assignee: United Monolithic Semiconductors S.A.S., Orsay Cedex (FR)

(21) Appl. No.: 11/722,329

(22) PCT Filed: Dec. 7, 2005
(86) PCT No.: PCT/EP2005/056583

§ 371 Date: Oct. 30, 2009

(30) Foreign Application Priority Data
Dec. 20, 2004 (FR) 04/13584

(51) Int. Cl. H01L 23/04; H01L 21/50

(52) U.S. Cl. 257/728; 438/112; 257/E23.181; 257/E21.499

(57) ABSTRACT

The invention relates to a miniature microwave package comprising a microwave chip (60) having an active face (62). The chip includes a protective lid (72) fixed to the active face, at least partially covering it, the lid including at least one recess forming, with the active face of the chip, a cavity (94, 96, 98). The invention is used in miniature microwave packages.

The invention relates to a miniature package for the encapsulation of microwave integrated circuits operating up to frequencies of 200 GHz, and especially for the protection of the encapsulated integrated circuit in the package.

The development of microwave applications at increasingly high frequencies has resulted in an increasing demand for integrated circuits with a high level of integration and compactness.

The microwave packages of the prior art use for example organic (PCB) or ceramic technologies. The common principle of these packages consists in mounting an electronic chip in a package and interconnecting it mainly via conducting wires in the case of circuits comprising microstrip lines or, more rarely, by solder bumps in the case of uniplanar circuits. The integrated circuit is protected from physical, chemical or other forms of attack coming from the external environment, in particular by sealing the package with a lid.

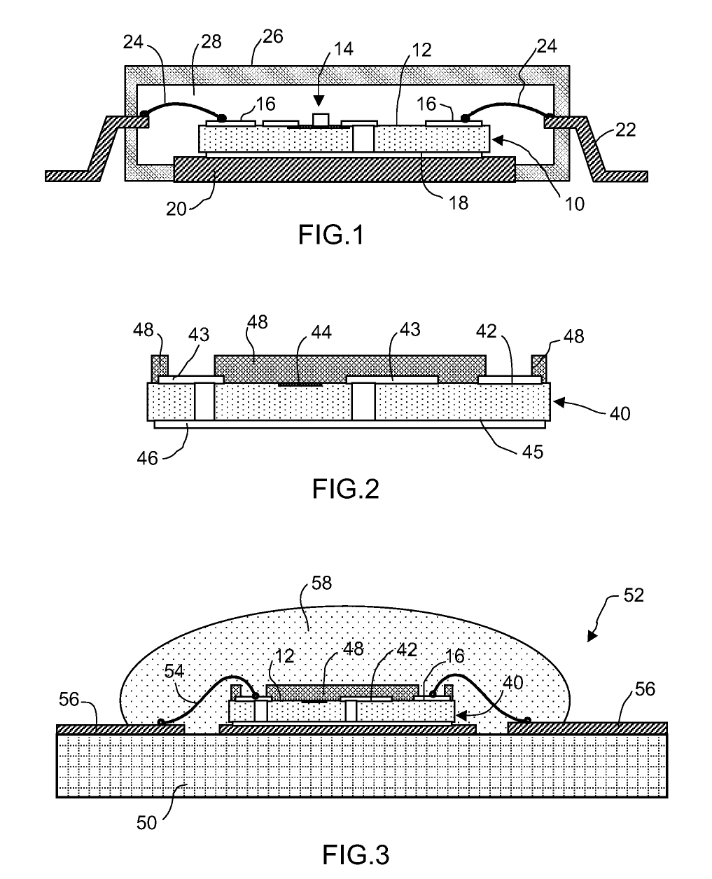

FIG. 1 shows an example of the construction of a microwave package of the prior art commonly referred to as an MMIC (monolithic microwave integrated circuit) operating in frequency ranges between 1 GHz and 100 GHz.

The microwave package shown in FIG. 1 essentially comprises a microwave chip 10 having an active face 12, integrating active microwave components 14, especially transistors, and electrical conductors 16, and, opposite the active face, a rear face 18. The chip 10 is mounted via its rear face 18 on a metal bottom 20 of the microwave package. The package includes electrical contacts in the form of metal leads 22 for mounting on an interconnection circuit (or receiving circuit), this not being shown in the figure.

The metal leads 22 of the package shown in FIG. 1, which are mechanically fastened to the package, provide the electrical connections between the chip and the environment external to the package by means of electrical wires 24 connecting the electrical conductors 16 on the active face of the chip to the metal leads 22 of the package.

The package shown in FIG. 1 is sealed by a lid 26, which protects the chip from the external environment. The chip is therefore in an air (or gas-filled) cavity 28 formed by the package sealed by its lid.

The microwave package shown in FIG. 1 is intended to be mounted on an electronic card, for example in order to interconnect it with other electronic circuits.

FIGS. 2 and 3 show two other techniques of the prior art for protecting integrated circuits.

FIG. 2 shows a microwave chip 40 having an active face 42, which includes electrical conductors 43 on the active face, the active face integrating active microwave components 44, and, opposite the active face, a rear face 45 that includes electrical conductors 46 on the rear face.

The integrated circuit 40 is protected by depositing a protective dielectric layer 48 with a thickness of a few microns on the active face 42 of the chip (BCB (benzocyclobutene) technology), thus protecting the delicate elements of the integrated circuit, such as the transistors or air bridges.

In FIG. 3, the integrated circuit 40 including the protective dielectric layer 48 on the active face 42 is mounted on a substrate 50 of a microwave package 52. The electrical conductors 16 on the active face 12 of the chip are electrically connected via wires 54 to electrical connectors 56 on the package.

Once the chip 40 has been mounted and assembled on the substrate 50, the package 52 is sealed by depositing a layer (or glob) 58 of dielectric (“glob top” technology) over the entire integrated circuit 40, protecting it from the external environment.

These various solutions of the prior art for protecting the integrated circuits of microwave packages have drawbacks, in particular:
the footprint of existing packages (around 20 mm²);
the reduction in electrical performance, in particular in high-speed, especially microwave, logic and analog applications, this being due to the length of the interconnections (bonding wires, transition lines, etc.) and to the parasitic elements associated with the dimensions of the packages of the prior art. In particular the resulting parasitic inductance of these packages, which limit the gain, stability and operating frequency of the encapsulated circuit;
the incompatibility of certain package solutions of the prior art with surface mounting techniques; and
the need for production equipment for testing the packaged components (fixture test, handler, etc.).

Furthermore, the main drawbacks of the solutions based on protective dielectrics are:
the appreciable reduction in performance, in particular for microwave applications, due to the use of the dielectric, which has the effect of increasing the parasitic capacitances in the active components (transistors) and passive components; and
the reduction in electrical performance, in particular in high-speed logic and analog applications, this being due to the length of the bonding wires.

To alleviate the drawbacks of the microwave packages of the prior art, the invention proposes a miniature microwave package comprising a microwave chip having an active face, characterized in that the chip includes a protective lid fixed to the active face, at least partially covering it, the lid including at least one recess forming, with the active face of the chip, a cavity.

In a preferred embodiment of the package according to the invention, the lid covers the entire active face of the chip.

In other embodiments of the package according to the invention, the lid includes several recesses, each of the recesses forming, with the active face of the chip, a cavity.

A main object of the invention is to provide a low-cost miniature microwave package of very high performance and operating up to frequencies of 200 GHz.

Another object of this invention is to provide a miniature microwave package compatible with surface mounting technologies (SMD, or surface mount devices).

Another objective of this invention is to provide a complete protection of the active face of the integrated circuit encapsulated in its package, making it more robust and easier to handle.

The invention also relates to a process for the collective fabrication of the packages, thereby reducing the fabrication cost of the packages.

The invention will be better understood with the aid of exemplary embodiments of miniature microwave packages with reference to the appended figures in which:

FIG. 1, already described, represents an exemplary embodiment of a microwave package of the prior art;

FIGS. 2 and 3, already described, show two other techniques for protecting integrated circuits of the prior art;

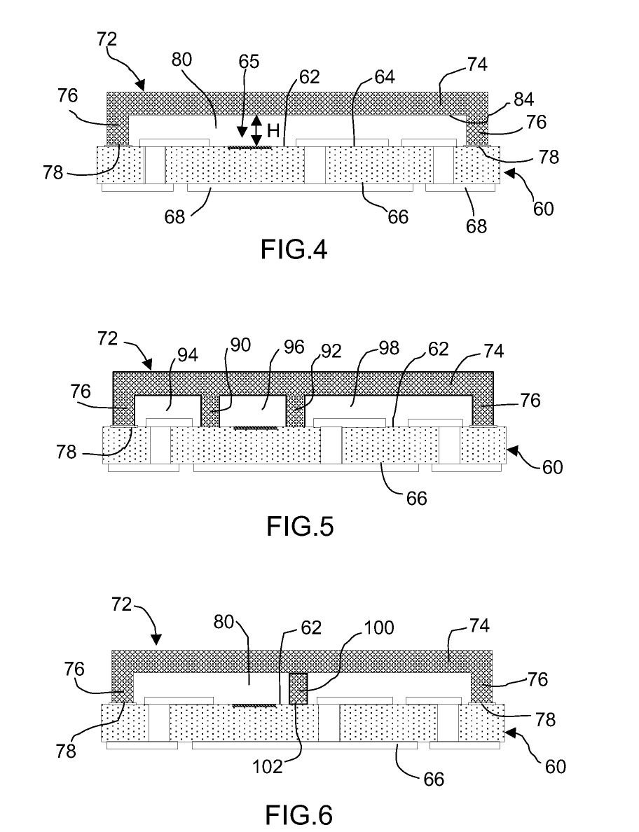

FIG. 4 shows a microwave package according to the invention;

FIG. 5 shows a first variant of the package of FIG. 4;

FIG. 6 shows a second variant of the package of FIG. 4;

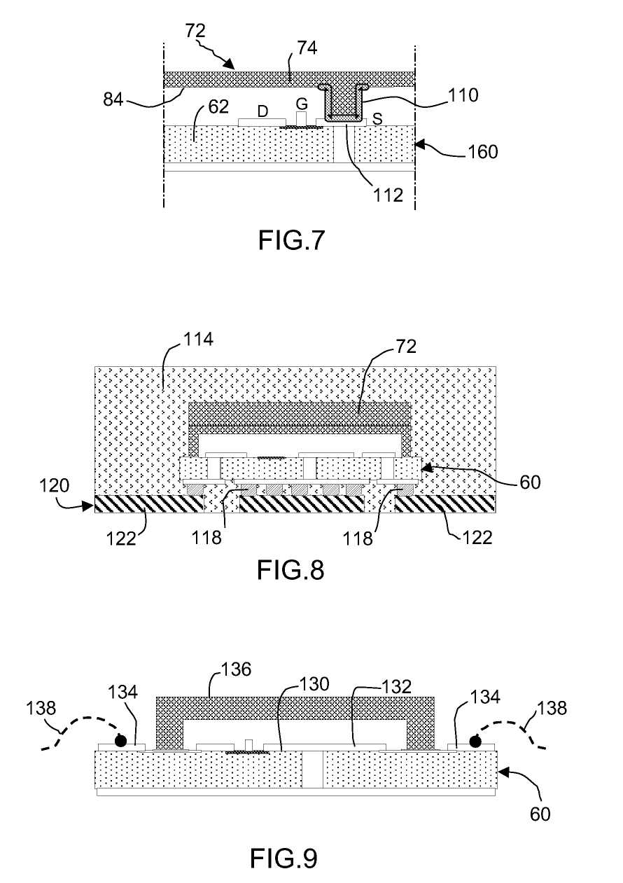

FIG. 7 shows a partial view of a third variant of the package of FIG. 4;

FIG. 8 shows another embodiment of the microwave package according to the invention;

FIG. 9 shows another embodiment of a microwave package according to the invention, which includes a lid with a smaller area than that of the active face of the chip;

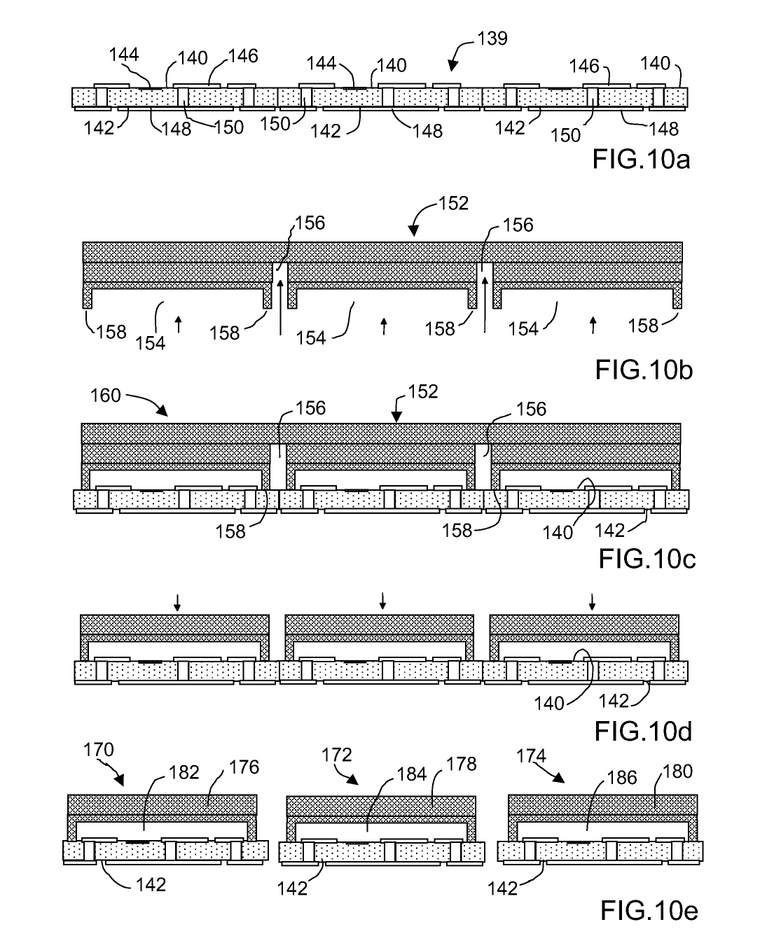

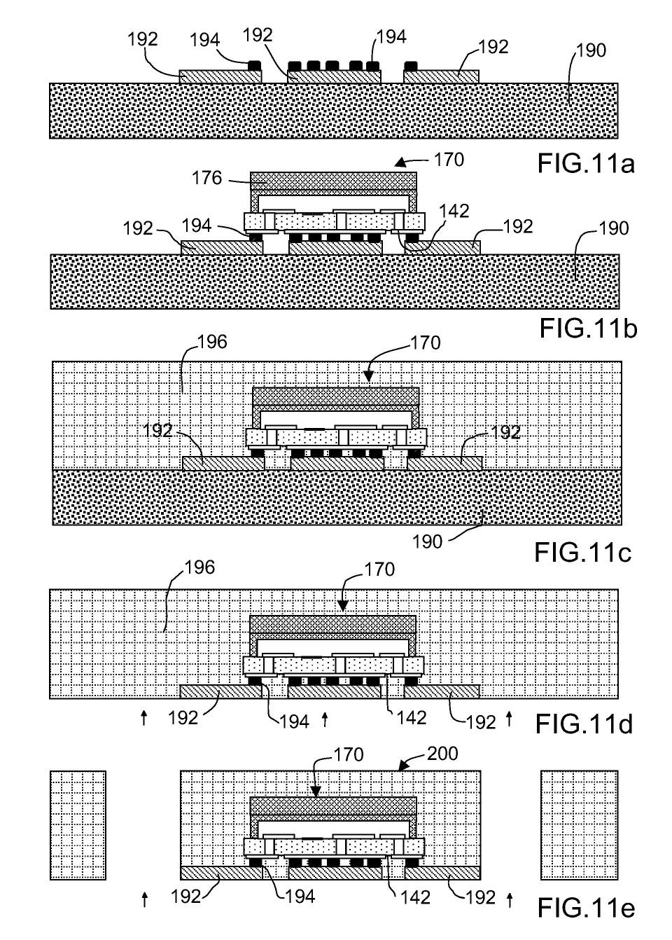

FIGS. 10a, 10b, 10c, 10d and 10e show the main steps of a first process for the collective fabrication of packages according to the invention; and

FIGS. 11a, 11b, 11c, 11d and 11e show a process for encapsulating an integrated circuit protected by a lid according to the invention.

FIG. 4 shows a microwave package according to the invention, which includes a microwave chip (or integrated circuit) 60 having an active face 62, which includes electrical conductors 64 on the active face, the active face integrating active microwave components 65, and, opposite the active face, a rear face 66 that includes electrical conductors 68 on the rear face for mounting the integrated circuit on a receiving substrate (not shown in the figure), for example for interconnecting it with other integrated circuits or for encapsulating it in a molded package.

The integrated circuit 60 includes a protective lid 72 having an upper plate 74 parallel to the active face 62 of the chip. The upper plate 74 is extended by walls 76 perpendicular to the plate and terminating in ends 78 in contact with the active face 62 of the chip so as to form, with the chip, a cavity 80 lying between the upper plate 74 of the lid and the active face.

The lid 72, mounted on the chip by known methods, covers the entire active face 62.

The lid 72, having an area close to or smaller than that of the integrated circuit 60 and of very small thickness is preferably produced in a material chosen from silicon, plastic, diamond, glass, organic or polymeric material, metal.

FIG. 5 shows a first variant of the package of FIG. 4. In this first variant, the lid 72 has other walls 90, 92 that are perpendicular to the upper plate 74 of the lid so as to form, with the active face 62 of the chip, several other cavities 94, 96, 98.

The advantage of a lid forming, with the active face of the chip, several cavities is the ability to provide electromagnetic isolation between certain zones of the active face of the chip or between certain zones of the active face of the chip and the external environment. This isolation is achieved by sealing the package with the lid, without any other fabrication operation, thus simplifying the fabrication of the package.

Recesses in the lid, on the side facing the active face of the chip, may be produced either by etching or by molding, which recesses form, with said active face, the cavities 80, 94, 96, 98. The lid, in contact with the active face of the chip via the rims of the recesses of the plate form the cavities between the lid and the active face.

FIG. 6 shows a second variant of the package of FIG. 4. In this second variant, the lid 72 includes pillars 100 distributed beneath the upper plate 74 of the lid and in contact with the active face 62 of the chip via its end 102. These pillars are intended to support said lid 72 on the integrated circuit. For this purpose, the pillars have the same height H as the walls 76 of the lid, so that the walls 76 and the pillars 100 are in contact via their respective ends 78, 102 with the active face of the chip.

FIG. 7 shows a partial view of a third variant of the package of FIG. 4. In this third variant, the lid includes, on the face 84 of the plate 72, facing the active face 62 of the chip, electrical and thermal conductors 110 on the lid that are in contact with electrical conductors 112 on the active face.

In the embodiment shown in FIG. 7, the electrical conductor 112 on the active face is the source S of a field-effect transistor on the active face of the chip. The source S is connected to the ground of the lid 72, draining the heat generated by the transistor.

In general, the electrical and thermal conductors 110 on the lid provide, on the one hand, electrical connection with electrical conductors on the chip (for example ground conductors) and, on the other hand, draining of the heat generated by the chip into the lid.

In practical embodiments of the lid, the depth H of the recesses in the lid, or the depth of the cavities in the protected integrated circuit, is between 10 and 500 microns.

For certain applications of the microwave chips, the cavities formed by the lid with the integrated circuit are used to produce microwave filters or waveguides.

In another embodiment of a microwave package according to the invention, shown in FIG. 8, the integrated circuit 60 including the protective lid 72 is mounted via electrical contacts 118 (for example solder bumps) on a bottom 120 of the package, which includes an array of electrical connectors 122, or leadframe, for mounting the package on a receiving circuit having a lower electrical conductor resolution than that of the integrated circuit 60.

The package of FIG. 8 is sealed by a molding 114 encapsulating the chip 60 with its protective lid 72 leaving the electrical contacts 112, for interconnecting the package to a receiving circuit, exposed.

FIG. 9 shows another embodiment of a microwave package according to the invention, which includes a lid of smaller area than that of the active face of the chip.

The package of FIG. 9 comprises the integrated circuit 60 having an active face 130, which includes electrical conductors 132 on the active face and, among these conductors on the active face, electrical connections 134 for electrically connecting the chip to an external circuit.

The chip is protected by a lid 136 fastened to the active face 130, having the same structure as the lid of the package of FIG. 4, but having a smaller area than the area of the active face of the chip, partially covering it for the purpose of leaving the electrical connections 134 of the chip exposed. The chip may be mounted on a receiving substrate (not shown in the figure) which includes electrical contacts. The electrical contacts of the substrate are then connected via interconnection wires 138 (shown in dotted lines) to the electrical connections 134 on the chip.

The invention also relates to a process for the collective fabrication of miniature microwave packages according to the invention.

FIGS. 10a, 10b, 10c, 10d, 10e show the main steps of a first process for the collective fabrication of miniature microwave packages comprising an integrated circuit protected by a lid, according to the invention.

The first process for the collective fabrication of the package according to the invention comprises at least the following steps:
fabrication using, for example, known techniques, on a single-crystal or wafer made of gallium arsenide or gallium nitride or indium phosphide, of a set of integrated circuits 139 (see FIG. 10a). Each of the integrated circuits has an active face 140 and, opposite the active face, a rear face 142, the active face including active elements 144 and electrical conductors 146 on the active face, the rear face 142 including electrical conductors 148 on the rear face. Plated-through holes 150 in the chip which connect the electrical conductors 146 on the active face to the electrical conductors 148 on the rear face;
fabrication of a lid wafer 152 from a silicon wafer etched (see FIG. 10b):
a) with recesses 154 intended for forming, with the active faces of the chips to be protected, cavities and
b) with dicing paths 156 between the lids, for separating the lidded integrated circuits;
localized deposition of an adhesive element on the rims 158 of the recesses 154;
mounting of the lid wafer 152 via the rims 158 of the recesses 154 onto the integrated-circuit wafer (of FIG. 10a) on the active faces 140 of the integrated circuits by wafer bonding, constituting an encapsulated-integrated-circuit wafer 160 (see FIG. 10c);
thinning of the encapsulated-integrated-circuit wafer 160 from the lid wafer 152 side, as far as the dicing paths 156 separating the lids for protecting the integrated circuits of the integrated-circuit wafer (see FIG. 10d); and
dicing of the encapsulated-integrated-circuit wafer 160 in order to separate the packages 170, 172, 174 comprising the integrated circuits protected by their respective lids 176, 178, 180 (see FIG. 10e).

The recesses 154 in the lids form, with their respective active faces, cavities 182, 184, 186.

FIGS. 11a, 11b, 11c, 11d and 11e show a process for encapsulating a package according to the invention which comprises an integrated circuit protected by a lid obtained for example according to the collective fabrication process described above with regard to FIGS. 10a to 10e.

The encapsulation process shown in FIGS. 11a to 11e comprises at least the following steps:
growth on a temporary substrate 190 of an array of electrical contacts 192, or leadframe, and solder bumps 194 on the electrical contacts 192 (see FIG. 11a);
mounting of the package 170 comprising an integrated circuit protected by its lid 176 via its rear face 142 on the array of electrical contacts 192 by means of the solder bumps 194 (see FIG. 11b);
molding 196 of the integrated circuit protected by its lid and of the array of electrical contacts 192 on the temporary substrate 190 (see FIG. 11c);
thinning of the temporary substrate 190 as far as the electrical contact 192 of the leadframe (see FIG. 11d); and
dicing and separation of a molded package 200 comprising the integrated circuit protected by its lid (see FIG. 11e).

The general concept of the invention may be exemplified in several solutions depending on the substrate used and certain modifications made to the integrated circuit.

To obtain shielding: by the use of a package of the prior art (leaded package or QFN-type package) for the overall encapsulation of the component.

To increase compactness: use of a “glob top”-type protection on the protected integrated circuit.

To improve hermeticity: by the use of a substrate and a ceramic lid.

To increase power: by the use of a substrate having a high thermal conductivity, chosen from diamond, AIN, BeO, etc., or of a standard low-cost (PCB, LTCC, HTCC, etc.) substrate with thermal vias. This encapsulation solution may be combined with MMIC integrated circuits thermally optimized by the use of thermal microvias beneath the transistors of the MMIC, by reducing the thickness of the MMIC.

The packages according to the invention comprising an integrated circuit protected by a lid also allow, in addition to the advantages already mentioned:
significant improvement in the thermal problem, by reducing the thermal path;
a fabrication process involving collective processing that is much less onerous than those of the prior art;
significant improvement in electrical performance in high-speed logic and analog applications, thanks to very short interconnections;
compatibility with production techniques involving surface mounting of components, also avoiding the use of bonding wires;
creation of a very small air cavity between the lid and the active face of the chip, adding no parasitic capacitances and making the circuit less sensitive to subsequent encapsulation or packaging operations. Furthermore, the cutoff frequencies of the higher modes of this cavity lie well outside the frequencies that can be used (in another embodiment, it is possible to choose the height of the cavities so as to produce rectangular waveguides or filters);
creation of an air cavity of very small dimensions, allowing the mechanical elements of MEMS (microelectromechanical system) components to move and therefore function;
possibility of adapting the height of the cavities in order to produce optical windows, dicing paths, and back shorts for integrated antennas;
compatibility with probe production test methods;
compatibility with current integrated circuit fabrication processes; and

protection affording better radiation hardening.

1. A miniature microwave package comprising:
a microwave chip having an active face, wherein the chip includes a protective lid fixed to the active face, at least partially covering the active face, wherein the lid includes at least one recess forming, with the active face of the chip, a cavity.

2. The miniature microwave package as claimed in claim 1, wherein the lid covers the entire active face of the chip.

3. The miniature microwave package as claimed in claim 1, wherein the lid includes several recesses, each of the recesses forming, with the active face of the chip, a cavity.

4. The miniature microwave package as claimed in claim 1, wherein the active face of the chip includes, on the active face, electrical conductors and active microwave components, the chip having, opposite the active face, a rear face which includes electrical conductors on the rear face, the protective lid for the integrated circuit having an upper plate parallel to the active face of the chip, the upper plate being extended by walls perpendicular to the plate and terminating in ends in contact with the active face of the chip so as to form, with the chip, a cavity lying between the upper plate of the lid and the active face.

5. The miniature microwave package as claimed in claim 4, wherein the lid has other walls that are perpendicular to the upper plate of the lid so as to form, with the active face of the chip, several other cavities.

6. The miniature microwave package as claimed in claim 3, wherein recesses in the lid, on the side facing the active face of the chip, are produced either by etching or by molding, which recesses form, with said active face, the cavities.

7. The miniature microwave package as claimed in claim 5, wherein the lid includes, on the face of the plate, facing the active face of the chip, electrical and thermal conductors on the lid that are in contact with electrical conductors on the active face.

8. The miniature microwave package as claimed in claim 4, comprising an integrated circuit having an active face, having electrical conductors on the active face and, among these conductors on the active face, electrical connections for electrically connecting the chip to an external circuit, the lid for protecting the chip having a smaller area than the area of the active face of the chip partially covering it, leaving the electrical connections of the chip exposed.

9. The miniature microwave package as claimed in claim 1, wherein the lid is preferably made of a material chosen from silicon, plastic, diamond, glass, organic or polymeric material, metal.

10. A process for the collective fabrication of miniature microwave packages comprising a microwave chip protected by a lid as claimed in claim 1, comprising the following steps:
fabricating, on a single-crystal or wafer made of gallium arsenide or gallium nitride or indium phosphide, of a set of integrated circuits, each of the integrated circuits having an active face and, opposite the active face, a rear face, the active face including active elements and electrical conductors on the active face, the rear face including electrical conductors on the rear face and plated-through holes in the chip which connect the electrical conductors on the active face to the electrical conductors on the rear face;
fabricating of a lid wafer from a silicon wafer etched:
a) with recesses intended for forming, with the active faces of the chips to be protected, cavities and
b) with dicing paths between the lids, for separating the lidded integrated circuits;
localized deposition of an adhesive element on the rims of the recesses;
mounting of the lid wafer via the rims of the recesses onto the integrated-circuit wafer on the active faces of the integrated circuits by wafer bonding, constituting an encapsulated-integrated-circuit wafer;
thinning of the encapsulated-integrated-circuit wafer from the lid wafer side, as far as the dicing paths separating the lids for protecting the integrated circuits of the integrated-circuit wafer; and
dicing of the encapsulated-integrated-circuit wafer in order to separate the packages comprising the integrated circuits protected by their respective lids.

11. A process for encapsulating an integrated circuit protected by a lid as claimed in claim 1, comprising the following steps:
growth on a temporary substrate of an array of electrical contacts, or leadframe, and solder bumps on the electrical contacts;
mounting of the package comprising an integrated circuit protected by its lid via its rear face on the array of electrical contacts by means of the solder bumps;
molding of the integrated circuit protected by its lid and of the array of electrical contacts on the temporary substrate;
thinning of the temporary substrate as far as the electrical contact (192) of the leadframe; and
dicing and separation of a molded package comprising the integrated circuit protected by its lid.

12. The miniature microwave package as claimed in claim 2, wherein the lid includes several recesses, each of the recesses forming, with the active face of the chip, a cavity.
